(19) United States
(12) Patent Application Publication
(10) Pub. No.: US 2009/0147607 A1
(43) Pub. Date: Jun. 11, 2009

(54) RANDOM ACCESS MEMORY AND DATA REFRESHING METHOD THEREOF

(75) Inventor: Shu-Liang Nin, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 12/056,278

(22) Filed: Mar. 27, 2008

(30) Foreign Application Priority Data
Dec. 7, 2007 (TW) 96146911

(51) Int. Cl. G11C 11/403; G11C 8/10

(52) U.S. Cl. 365/222; 365/230.02; 365/230.06

(57) ABSTRACT

A random access memory and a data refreshing method thereof are provided. The random access memory includes a memory array having a plurality of word lines; a control logic unit which is used for outputting a refreshment indicating signal, a thermal sensor which is used for outputting a temperature indicating signal; a refresh counter which is used for outputting a row address counting signal; and a row address decoder which is used for performing a decoding operation on the row address counting signal in response to the refreshment indicating signal and the temperature indicating signal, and simultaneously enabling the plurality of word lines of the memory array based on a result of the decoding operation.

### CROSS-REFERENCE TO RELATED APPLICATION

This application claims the priority benefit of Taiwan application serial no. 96146911, filed on Dec. 7, 2007. The entirety the above-mentioned patent application is hereby incorporated by reference herein and made a part of specification.

### BACKGROUND OF THE INVENTION

1. Field of the Invention

The present invention relates to a random access memory and a data refreshing method thereof, and particularly relates to a random access memory and a data refreshing method thereof for accelerating data refreshing speed.

2. Description of Related Art

A dynamic random access memory (DRAM) is a dynamic medium for data storage, and the data stored therein requires frequent refresh to maintain the accuracy of the data. However, as the frequency of operating a dynamic random access memory increases, the heat incurred by high-speed operation has caused evident influence on the accuracy of the data stored in a dynamic random access memory. The main reason is that the time which the data is retained in a dynamic random access memory decreases as the temperature of the dynamic random access memory increases. Thus, when a dynamic random access memory is operated in high temperature, the data refreshing speed needs to be increased so as to prevent the loss and inaccuracy of the stored data.

To overcome the aforesaid defects, some manufacturers in this field dispose an inbuilt thermal sensor in a dynamic random access memory. When the dynamic random access memory is under a power-saving mode and performing self refresh, a central processing unit (CPU) receives a temperature indicating signal outputted from the thermal sensor and varies the data refreshing speed of the dynamic random access memory accordingly. This improvement, however, does not eliminate the influence of heat on the accuracy of data stored in the dynamic random access memory. The reason can be explained by the data refreshing method of a dynamic random access memory. There are two kinds of data refreshing methods of a dynamic random access memory. One method is to perform self refresh while the dynamic random access device is under power-saving mode, and the other is to perform auto refresh while the dynamic random access is under a normal writing or reading operation. When the dynamic random access memory performs self refresh under power-saving mode, the central processing unit does not access a large volume of data from the dynamic random access memory, and causes less power consumption and less heat, which consequently has less influence on the accuracy of the data stored in the dynamic random access memory.

On the contrary, when performing auto refresh under a normal writing or reading operation, the dynamic random access memory correspondently enables a word line to perform data refreshment on a memory cell connected to the word line only upon receiving a refreshment indicating signal from the central processing unit. Under a normal writing or reading operation, the central processing unit accesses a large volume of data and generates great heat in the dynamic random access memory. As a result, the central processing unit is not able to read a temperature indicating signal outputted from the thermal sensor and outputs a data refreshment indicating signal at regular frequency, which results in the heat seriously influencing the accuracy of data stored in the dynamic random access memory.

### SUMMARY OF THE INVENTION

One aspect of the present invention provides a random access memory, which varies a data refreshing speed according to a temperature indicating signal outputted from a thermal sensor without changing a frequency of outputting a data refreshing indicating command from a central processing unit or other similar controllers.

Another aspect of the present invention provides a data refreshing method, which enables a random access memory to vary a data refreshing speed according to a temperature indicating signal outputted from a thermal sensor without changing a frequency of outputting a data refreshing indicating command from a central processing unit or other similar controllers.

Another aspect of the present invention provides a random access memory, which comprises a memory array, a control logic unit, a thermal sensor, a refresh counter, and a row address decoder. The memory array has a plurality of word lines. The control logic unit is used for outputting a refreshment indicating signal to the row address decoder. The thermal sensor is used for outputting a temperature indicating signal to the address decoder. The refresh counter is used for outputting a row address counting signal to the address decoder. The row address decoder is used for performing a decoding operation on the row address counting signal in response to the refreshment indicating signal and the temperature indicating signal, and enabling the plurality of word lines of the memory array based on a result of the decoding operation.

Yet aspect of the present invention provides a data refreshing method applicable to a random access memory, wherein the random access memory comprises a thermal sensor which generates a temperature indicating signal, a refresh counter which outputs a row address counting signal, and a plurality of word lines. The method comprises the following processes. First, a refreshment indicating signal is generated. Then, a decoding operation is performed on the row address counting signal in response to the refreshment indicating signal and the temperature indicating signal such that a result of the decoding operation is able to simultaneously enable the plurality of word lines of the memory array.

Still aspect of the present invention enables the row address decoder to perform the decoding operation on the row address counting signal in response to the refreshment indicating signal and the temperature indicating signal, and when a central processing unit or other similar controllers outputs a data refreshing indicating command, the row address decoder simultaneously enables a plurality of word lines based on an result of the decoding operation. Consequently, the speed of data refreshment is increased, and the central processing unit or other similar controllers do not need to vary the frequency of outputting the data refreshing indicating command.

To make the above and other objectives, features, and advantages of the present invention more comprehensible, several embodiments accompanied with figures are described in details as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram illustrating a portion of the devices in a dynamic random access memory 100 according to an embodiment of the present invention.

FIG. 2 is a process flow illustrating a data refreshing method according to an embodiment of the present invention.

### DESCRIPTION OF EMBODIMENTS

To clearly explain and to compare the present invention with the previous art in this field, a dynamic random access memory is given as an example in the following embodiments. The present invention, however, is not limited thereto.

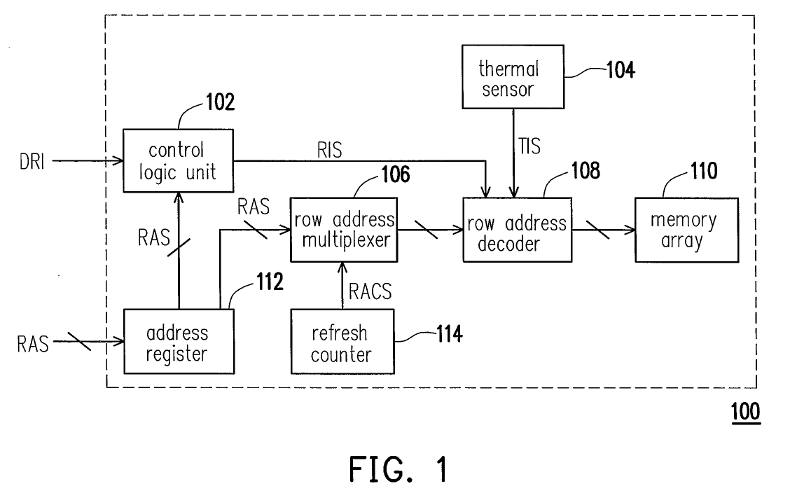

FIG. 1 is a block diagram illustrating a portion of the devices, mainly related to an operation of data refreshment in a dynamic random access memory 100 according to an embodiment of the present invention. Referring to FIG. 1, a control logic unit 102, a thermal sensor 104, a row address multiplexer 106, a row address decoder 108, a memory array 110, an address register 112, and a refresh counter 114 are shown.

The memory array 110 in FIG. 1 has a plurality of word lines (not shown). The control logic unit 102 is used for decoding a data refreshing indicating command (DRI) transmitted from an outside terminal of the dynamic random access memory 100 into a refreshment indicating signal (RIS), and the data refreshing indicating command (DRI) is provided by a central processing unit (not shown) or other similar controllers (not shown). The address register 112 is used for registering a row address signal (RAS) transmitted from the outside terminal of the dynamic random access memory 100, and transmitting the row address signal (RAS) to the control logic unit 102 and the row address multiplexer 106.

The refresh counter 114 counts the word line addresses requiring refreshment according to the frequency of the refreshment indicating signals outputted from the control logic unit 102, and outputs a row address counting signal (RACS) accordingly. Besides receiving the row address signal (RAS), the row address multiplexer 106 receives the row address counting signal (RACS) and selects either the row address signal (RAS) or the row address counting signal (RACS) to output. When the row address decoder 108 receives the refreshment indicating signal (RIS), the row address multiplexer 106 selects the row address counting signal to output. The thermal sensor 104 is used for detecting the temperature of the dynamic random access memory 100 and outputting a temperature indicating signal (TIS) accordingly. The row address decoder 108 is used for receiving an output from the row address multiplexer 106, the refreshment indicating signal (RIS) and the temperature indicating signal (TIS).

When the dynamic random access memory 100 performs auto refresh under an normal writing or reading operation, the central processing unit or other similar controllers output the data refreshing indicating command (DRI) to the dynamic random access memory 100 intermittently, and the row address multiplexer 106 outputs the row address counting signal (RACS) correspondently so that the row address decoder 108 performs a decoding operation on the row address counting signal (RACS) in response to the refreshment indicating signal and the temperature indicating signal (TIS). Thereafter, the row address decoder 108 simultaneously enables a plurality of word lines of the memory array 110 accordingly. The quantity of the word lines enabled is, for example, two or four, which is variable according to actual requirement. Consequently, whenever the central processing unit or other similar controllers output the data refreshing indicating command (DRI), the row address decoder 108 enables at least two word lines to accelerate the speed of data refreshment. Moreover, another advantage of the data refreshing method is that the central processing unit or other similar controllers do not need to vary the frequency of outputting the data refreshing indicating command.

If the temperature indicating signal (TIS) has a bit only, a temperature threshold value is set to the temperature sensor 104, and the temperature sensor 104 detects whether the temperature of the dynamic random access memory 100 exceeds the temperature threshold value to determine the value of the bit. Similarly, if a temperature indicating signal (TIS) has a plurality of bits, more temperature threshold values is set to the thermal sensor 104, and accordingly the row address decoder 108 varies the quantity of the word lines enabled. In addition, a refreshment indicating signal (RIS) may be directly provided from outside terminal of the dynamic random access memory 100.

Although a dynamic random access memory is given as an example in above embodiments, the aforesaid data refreshing method is not limited to a dynamic random access memory. The data refreshing method is applicable in every kind of random access memory, which requires data refreshment.

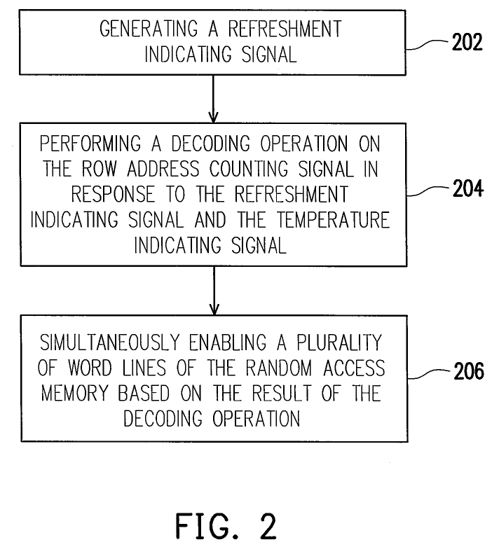

From the above-mentioned embodiments, a data refreshing method applicable to a random access memory is deduced, wherein the random access memory comprises a thermal sensor which generates a temperature indicating signal according to the temperature of the random access memory, a refresh counter which outputs a row address counting signal, and a plurality of word lines. A process flow of this method is shown in FIG. 2. FIG. 2 is a process flow illustrating a data refreshing method according to an embodiment of the present invention. Referring to FIG. 2, a refreshment indicating signal is generated first (shown as 202). Then, a decoding operation is performed on the row address counting signal in response to the refreshment indicating signal and a temperature indicating signal (shown as 204). A plurality of word lines of the random access memory is simultaneously enabled based on the result of the decoding operation (shown as 206).

To sum up, the present invention enables the row address decoder to perform the decoding operation on the row address counting signal in response to the refreshment indicating signal and the temperature indicating signal, and when the central processing unit or other similar controllers outputs the data refreshing indicating command, the row address decoder simultaneously enables a plurality of word lines according to the result of the decoding operation. Consequently, the speed of data refreshment is increased, and the central processing unit or other similar controllers do not need to vary the frequency of outputting the data refreshing indicating command.

Although the present invention has been disclosed by the above embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A random access memory, comprising:
a memory array having therein a plurality of word lines;
a control logic unit for outputting a refreshment indicating signal to a row address decoder;
a thermal sensor, which is used for outputting a temperature indicating signal to the address decoder; and
a refresh counter, which is used for outputting a row address counting signal to the address decoder; wherein the row address decoder performs a decoding operation on the row address counting signal in response to the refreshment indicating signal and the temperature indicating signal, and enables the plurality of word lines of the memory array based on a result of the decoding operation.

2. The random access memory in claim 1, wherein the control logic unit is used for decoding a data refreshing indicating command transmitted from an outside terminal of the random access memory into the refreshment indicating signal.

3. The random access memory in claim 2 further comprising a row address multiplexer which is used for receiving the row address counting signal and a row address signal transmitted from the outside terminal of the random access memory, and selectively outputting the row address signal and the row address counting signal for the decoding operation of the row address decoder; wherein the row address multiplexer outputs the row address counting signal when the row address decoder receives the refreshment indicating signal.

4. The random access memory in claim 1, wherein the row address decoder simultaneously and selectively enables a first set of two word lines and a second set of four word lines based on the result of the decoding operation of the row address decoder.

5. A data refreshing method to enable word lines of a random access memory having a thermal sensor which generates a temperature indicating signal, a refresh counter which outputs a row address counting signal, and a plurality of word lines; the data refreshing method comprises the steps of:
generating a refreshment indicating signal; and
performing a decoding operation on the row address counting signal in response to the refreshment indicating signal and the temperature indicating signal such that a result of the decoding operation is able to simultaneously enable the plurality of word lines of the random access memory.

6. The data refreshing method in claim 5 wherein the random access memory further comprises a control logic unit which is used for decoding a data refreshing indicating command transmitted from an outside terminal of the random access memory and transforming into the refreshment indicating signal.

7. The data refreshing method of claim 5, wherein the quantity of the word lines enabled is two.

8. The data refreshing method of claim 5, wherein the quantity of the word lines enabled is four.
